(19) United States
(12) Patent Application Publication
(10) Pub. No.: US 2010/0015357 A1
(43) Pub. Date: Jan. 21, 2010

(54) CAPACITIVELY COUPLED PLASMA ETCH CHAMBER WITH MULTIPLE RF FEEDS

(76) Inventors: Hiroji Hanawa, Sunnyvale, CA (US); Saturo Kobayashi, Mountain View, CA (US); Lawrence Wong, Fremont, CA (US)

Correspondence Address: APPLIED MATERIALS/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/175,745

(22) Filed: Jul. 18, 2008

(51) Int. Cl. H05H 1/02; C23C 16/00

(52) U.S. Cl. 427/570; 118/723 I

(57) ABSTRACT

A capacitive plasma discharge system employing multiple feeds of RF source power across an area of an electrode. Multiple RF feed locations across the electrode allow for control of the axial electric field across a radius at various azimuth angles of a plasma processing chamber. In an embodiment, a first RF power feed is coupled to a center of an electrode of the capacitively coupled chamber. The first RF power feed is further coupled to a first RF match network. A second RF power feed is coupled to the electrode at a first radius from the first RF power feed and at a first azimuth angle. The second RF power feed is further coupled to a second RF match network.

### BACKGROUND

1. Field

Embodiments of the present invention relate to the electronics manufacturing industry and more particularly to a capacitively coupled plasma processing apparatus.

2. Discussion of Related Art

Plasma processing systems are ubiquitous in semiconductor fabrication. While there are a number of plasma chamber and discharge designs, the capacitively coupled plasma discharger continues to be a mainstay of the industry. Generally, such a system includes a first and second electrode arranged in a parallel plate configuration. At least one of the electrodes is powered by an RF generator typically operating at an industrial frequency band around 13.56 MHz. Each electrode is typically a planar, circular disc to be substantially the same shape, albeit of a larger diameter, as the substrate (e.g., a semiconductor wafer). It is conventional to couple the RF generator to an electrode by way of an “RF feed” at the center, half the electrode diameter, of the disc-like electrode to provide radial symmetry.

Such capacitive plasma discharges continue to be employed as semiconductor device feature dimensions are scaled down. Device scaling, however, is not without issue because a capacitive plasma discharge must meet ever more demanding uniformity requirements to at least maintain yields comparable to those for devices of bygone technology generations. Along with the reductions in feature size, economies of scale have lead to increases in the size of semiconductor substrates to 300 mm diameters. As such, substrate scaling has also increased uniformity demands on a capacitive plasma discharge. For example, less than a 3% range across a 300 mm substrate may now be necessary while such a range across a 200 mm substrate was at one time more than adequate for reasonable device yields.

Furthermore, along with feature dimensions scaling down and substrate dimension scaling up, demands on equipment throughput continue to increase. While high frequency capacitive RF discharges have been investigated in the past as a potential means to increase film etch rates and thereby improve throughput, such discharges typically suffer from relatively higher process non-uniformity. Improving the across-wafer uniformity of a capacitive RF discharge is, highly desirable.

### SUMMARY

Embodiments of the present invention describe a capacitive plasma discharge system employing multiple feeds of RF power across an area of an electrode and a method to improve plasma uniformity. As described, the multiple RF feed locations across the electrode allow for control of the electric field both radially and across azimuth angles of a plasma processing chamber. In particular embodiments, these methods may be employed in combination with a high frequency RF generator, operating at 50 MHz or higher, to improve the uniformity of an etching process, such as a dielectric etch.

In an embodiment, a first RF power feed is coupled to a center of an electrode of the capacitively coupled chamber, the first RF power feed is further coupled to a first RF match network. A second RF power feed is coupled to the electrode at a first radius from the center position and a first azimuth angle, wherein the second RF power feed is further coupled to a second RF match network. The plasma uniformity may then be controlled by apportioning the total RF power provided to the disc-shaped electrode across the plurality of RF feeds.

In one embodiment, the first RF match network is coupled to a first RF power generator and the second RF match network is coupled to a second RF power generator. The first and second RF power generators may generate power at the same RF frequency, between 13.56 MHz and 162 MHz. and preferably between 50 MHz and 100 MHz. In one such embodiment, apportioning the total RF power during plasma processing of a substrate further comprises setting the first RF power generator coupled to the first RF match network to a first output power and setting the second RF power generator coupled to the second RF match network to a second output power.

In another embodiment, the first RF match network and the second RF match network are both coupled to a first RF power generator, with a power splitter. In still another embodiment, the first or second RF match network is coupled to an RF generator and the other is coupled to a dummy load, such as a 50 ohm load rated for between 100 and 1000 watts continuous power. In one such embodiment, apportioning the total RF power during plasma processing of a substrate further comprises setting the first RF power generator, coupled to the first RF feed through the first RF match network, to a first output power and setting the second RF match network, coupled to the first dummy load, to dissipate an amount of RF power tapped from the second RF feed.

Other embodiments provide for a computer control of the RF power across the multiple feeds coupled across the area of an electrode in a capacitively coupled etch chamber to control the uniformity of an etch process during machine execution of an etch process recipe.

### BRIEF DESCRIPTION OF THE DRAWINGS

Embodiments are illustrated by way of example, and not limitation, in the figures of the accompanying drawings in which:

FIG. 1A schematically illustrates a cross-sectional view of a capacitively coupled plasma etch system including a single RF generator coupled to an electrode by a plurality of RF feeds via a power splitter and a plurality of RF matches, in accordance with one embodiment;

FIG. 1B schematically illustrates a plane view of the electrode of FIG. 1A depicting multiple RF feed locations, in accordance with one embodiment;

FIG. 1C schematically illustrates a cross-sectional view of a capacitively coupled plasma etch system including a single RF generator coupled to an electrode at four RF feed locations via a plurality of power splitters and a plurality of RF matches, in accordance with one embodiment;

FIG. 1D schematically illustrates a cross-sectional view of a capacitively coupled plasma etch system including a plurality of RF generators coupled through a plurality of RF matches to an electrode at a plurality of RF feed locations, in accordance with one embodiment;

FIG. 1E schematically illustrates a cross-sectional view of a capacitively coupled plasma etch system including an RF generator coupled through a first RF match to an electrode at a first RF feed location and a RF dummy load coupled to the electrode through a second RF match at a second RF feed location, in accordance with one embodiment;

FIG. 2A schematically illustrates an axial component of electric field in the first order capacitor mode of a capacitively coupled plasma;

FIG. 2B schematically illustrates an axial component of electric field in the second order capacitor mode of a capacitively coupled plasma;

FIG. 3A depicts a measured etch rate uniformity map of a substrate etched with a capacitively coupled plasma energized with an RF generator coupled to a single RF feed positioned at the center of an electrode;

FIG. 3B depicts an azimuthal distribution of electric field in a capacitively coupled plasma energized through a single center RF feed as modeled based on the first order capacitor mode of a capacitively coupled plasma;

FIG. 3C depicts a measured etch rate uniformity map of a substrate etched with a capacitively coupled plasma energized with an RF generator coupled to a single RF feed positioned near an edge of an electrode;

FIG. 3D depicts an azimuthal distribution of electric field in a capacitively coupled plasma energized with an RF generator coupled to a single RF feed positioned near an edge of an electrode as modeled based on the second order capacitor mode of a capacitively coupled plasma;

FIG. 3E depicts a measured etch rate uniformity map of a substrate etched with a capacitively coupled plasma energized with an RF generator coupled to a first RF feed positioned at the center of an electrode and a second RF feed positioned near an edge of the disc-shaped electrode; in accordance with one embodiment;

FIG. 3F depicts a modeled azimuthal distribution of electric field in a capacitively coupled plasma energized with an RF generator coupled to a first RF feed positioned at the center of an electrode and a second RF feed positioned near an edge of the disc-shaped electrode; in accordance with one embodiment of the present invention;

FIG. 4A schematically illustrates an axial component of electric field in the first order surface mode of a capacitively coupled plasma;

FIG. 4B schematically illustrates an axial component of electric field in the second order surface mode of a capacitively coupled plasma;

FIG. 4C depicts an azimuthal distribution of electric field in a capacitively coupled plasma energized through a single center RF feed as modeled based on the second order surface mode of a capacitively coupled plasma; and

FIG. 5 depicts a dispersion curve illustrating first and second plasma surface modes as a function of inverse RF frequency.

### DETAILED DESCRIPTION

Embodiments of capacitive discharges employing multiple RF feeds across an area of an electrode are described herein with reference to figures. However, particular embodiments may be practiced without one or more of these specific details, or in combination with other known methods, materials, and apparatuses. In the following description, numerous specific details are set forth, such as specific materials, dimensions and processes parameters etc. to provide a thorough understanding of the present invention. In other instances, well-known semiconductor processes and manufacturing techniques have not been described in particular detail to avoid unnecessarily obscuring the present invention. Reference throughout this specification to “an embodiment” means that a particular feature, structure, material, or characteristic described in connection with the embodiment is included in at least one embodiment of the invention. Thus, the appearances of the phrase “in an embodiment” in various places throughout this specification are not necessarily referring to the same embodiment of the invention. Furthermore, the particular features, structures, materials, or characteristics may be combined in any suitable manner in one or more embodiments.

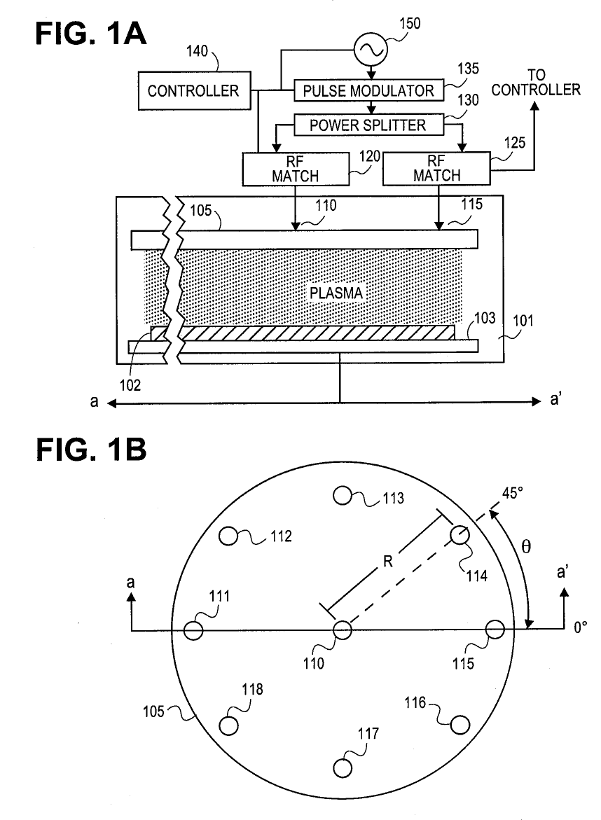

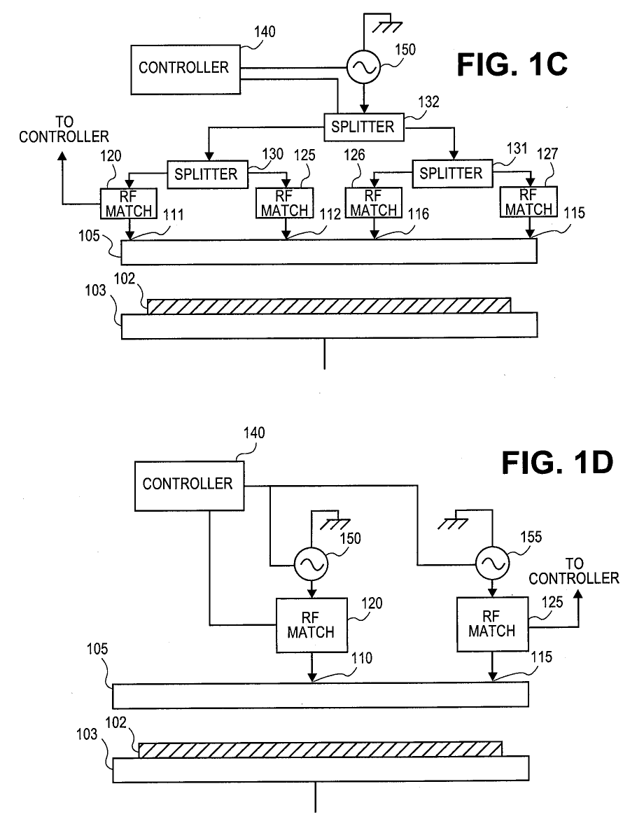

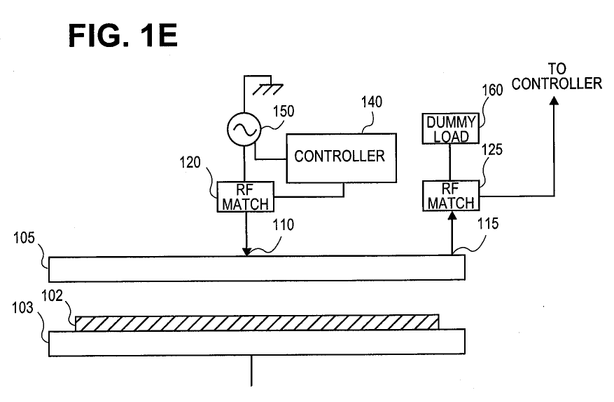

FIG. 1A schematically illustrates a partial cross-sectional view along the plane a-a′ of a capacitively coupled plasma etch system. In the depicted embodiment, the etch system includes a single RF generator 150 coupled to an electrode 105 at a first RF feed 110 and a second RF feed 115 positioned in different locations of the electrode 105. The RF feed 110 is further coupled to an RF impedance matching network, or an RF match 120, while the second RF feed 115 is further coupled to an RF match 125. In the particular embodiment depicted, a power splitter 130 divides the RF power from the RF generator 150 to the plurality of RF feeds 110 and 115. The power splitter 130 may be variable to selectively apportion RF power between the first RF feed 110 and the second RF feed 115 or may be a fixed value reconfigurable only through hardware modification. The capacitively coupled plasma etch system depicted further includes a pulse modulator 135 by which power from the RF generator 150 may be modulated across both the RF feeds 110 and 115 with a repetition frequency during processing. As further shown in FIG. 1A, a controller 140 is coupled to the first RF match 120, the second RF match 125, the power splitter 130, the pulse modulator 135 and the RF generator 150 to enable the etch system to be computer controlled. The controller 140 may be one of any form of general-purpose data processing system that can be used in an industrial setting for controlling the various subprocessors and subcontrollers. Generally, the controller 140 includes a central processing unit (CPU) in communication with memory and input/output (I/O) circuitry, among other common components.

During operation of the capacitively coupled plasma etch system, process gas within a process chamber 101 of the etch system is ionized into a plasma discharge when power is applied to the RF feeds 110 and 115. A capacitor is formed between the electrode 105 and a grounded electrode 103. The controller 140 may control power distribution of the RF signal provided from the RF generator 150 between the RF feeds 110 and 115 via the RF match 120 and 125 and/or via the power splitter 130 (if variable). As discussed elsewhere herein in further detail, the apportionment of power between the RF feeds 110 and 115 advantageously improves the uniformity of axial electric field of the capacitively coupled plasma across the area of the electrode 105. For example, in an etch process known to have a center high etch rate, such as an oxide etch process powered at 100 MHz, RF power can be apportioned toward the RF feed 115 at the periphery of the electrode 105 and away from the RF feed 110 at the center of the electrode 105. More specifically, in an oxide etch process wherein 1000 W of 100 MHz RF is provided by the RF generator 150, the power splitter 130 divides the power 1:1 between the RF feed 110 and the RF feed 115 to reduce the center high etch spot an increase the edge etch rate.

FIG. 1B schematically illustrates a plane view of the electrode 105 of FIG. 1A further depicting the first and second RF feeds, 110 and 115. In one embodiment, the electrode 105 is circular or disc-shaped with the first RF feed 110 coupled to the center of the electrode 105. In other embodiments, the electrode 105 may be square, rectangular, or otherwise irregularly shaped. As shown in the embodiment of FIG. 1B, the second RF feed 115 is physically coupled to the electrode 105 at a location described by a radius R from the first RF feed 110 and an azimuth angle θ relative to the reference plane a-a′. In the depicted embodiment, the plurality of RF feeds may further include the RF feeds 111-114 and 116-118 arranged about the area of the electrode 105. In the depicted embodiment, the plurality of RF feeds 111-118 are positioned at a fixed radial distance from the first RF feed 110 to form a group of RF feeds at the periphery of the electrode 105. However, in other embodiments, the plurality of RF feeds is coupled to the electrode 105 across a number of radial distances, for example to provide a constant a real density of RF feeds across the electrode 105.

In one embodiment, each of the plurality of the RF feeds 110-118 is coupled to an RF generator through a dedicated match. In another embodiment, only two or more of the plurality of RF feeds 110-118 is coupled to an RF generator, each of the two or more RF feeds being further coupled to a dedicated match. For such embodiments, the two or more RF feeds may be selected as a subset from the plurality of RF feeds 110-118 to provide RF power for the entire duration of a plasma etch step (i.e. a static subset). For example, only the RF feeds 110 and 115 may be provided in the etch system. In other embodiments, the two or more RF feeds may be selected from the plurality of RF feeds 110-118 configured in the hardware of the etch system. The two or more selected RF feeds may be a dynamic subset defined in a process recipe field to provide RF power across different ones of the plurality RF feeds during a plasma etch step. The dynamic subset may be modifiable during an etch process recipe to apportion RF power over time across selected ones of a larger plurality, such as the RF feeds 110-118. For example, each of the plurality of RF feeds 111-118 may be coupled to a switch (not shown) with the switch further coupled to at least one RF match with the RF match further coupled to an RF source. During operation of such an embodiment, the switch may connect the RF feed 115 to the RF match 125 for a first duration and then connect the RF feed 113 to the RF match 125 for a second duration while the RF feed 110 remains connected to the RF match 120 for both the first and second durations.

In particular embodiments, the RF signals provided to the plurality of RF feeds coupled to the electrode 105 are of a same, or common, RF frequency. In one such embodiment, the RF frequency provided to each of the plurality of RF feeds, such as for the RF feed 110 and the RF feed 115, is between about 13.56 MHz and about 162 MHz. Because higher etching rates can be achieved with higher RF frequencies, in a preferred embodiment the RF frequency provided to each of the plurality of RF feeds is between about 50 MHz and about 120 MHz. Thus, in the embodiment depicted in FIG. 1A, the RF generator 150 coupled to both the RF feed 110 and the RF feed 115 operates at between about 50 MHz and about 120 MHz. It has been found that for frequencies above 50 MHz, configurations providing a plurality of RF feeds as disclosed herein may provide a particularly significant improvement in plasma uniformity, as discussed further elsewhere herein.

In other embodiments, at least one of the plurality of RF feeds coupled to an electrode feeds both a first RF frequency and a second RF frequency. For example, the center RF feed 110 may be coupled to both the RF generator 150 having a first frequency (e.g., 100 MHz) and a second RF generator (not shown) having a second frequency (e.g., 2 MHz). In further embodiments, a high frequency RF generator is coupled to multiple RF feeds while a low frequency RF signal is coupled to only one of the multiple RF feeds. For example, the center RF feed 110 may be coupled to both the RF generator 150 having a first frequency (e.g., 100 MHz) and a second RF generator (not shown) operating at a second frequency (e.g., 2 MHz) while a second RF feed coupled to a second location of the electrode 105 (e.g., RF feed 115) is coupled only to the RF generator 150 operating at the first frequency (i.e. not coupled to the second RF generator operating a 2 MHz).

In other embodiments, the plurality of RF feeds includes more than two RF feeds. For example, the center RF feed 110 exciting a first order capacitive mode and two peripheral RF feeds exciting second order capacitive modes at orthogonal azimuth angles. FIG. 1C schematically illustrates a cross-sectional view of a capacitively coupled plasma etch system including the single RF generator 150 coupled to the disc-shaped electrode 105 at four RF feed locations, 111, 112, 116 and 115 through a plurality of power splitters 130, 131 and 132 and a plurality of RF matches, 120, 125, 126 and 127. As discussed elsewhere herein, because the second order capacitive modes have an azimuth angle dependency, it may be advantageous to have at least three RF feeds.

In alternative embodiments, a plurality of RF generators may be employed to directly power a plurality of RF feeds. For example, rather than the one or more RF power splitters employed in the embodiments depicted in FIGS. 1A and 1C, respectively, each of the plurality of RF feeds may be coupled to a dedicated RF power source as depicted in FIG. 1D. For example, the RF feed 110 may be coupled to the electrode 105 at a first location and further coupled to the dedicated RF match 120 and to the dedicated RF generator 150. The RF feed 115 may then be coupled to the electrode 105 at a second location and further coupled to the dedicated RF match 125 and a dedicated RF generator 155. Such a configuration has the benefit of being able to apportion power between the RF feed 110 and the RF feed 115 by merely adjusting the output of the RF generator 150 relative to the RF generator 155 via the controller 140. In such a configuration, the controller 140 may also ensure the phase of the signal from the RF generator 150 is matched to that from the RF generator 155. In further embodiments, a switch may be incorporated with the configuration depicted in FIG. 1D in a manner similar to that described in reference to FIG. 1A to allow a dynamic selection of two or more RF feeds from a larger plurality of RF feeds configured in the etch system hardware.

In still another embodiment, as depicted in FIG. 1E, the first RF feed 110 coupled to the electrode 105 at a first location is further coupled to the RF generator 150 through the RF match 120 while the second RF feed 115 is coupled to the electrode 105 at a second location and further coupled to an RF dissipator. The RF dissipator, for example, may be a purely resistive, 50 Ohm, dummy load 160. This configuration places an RF power shunt in parallel with the capacitive plasma load. RF power between the RF feed 110 and RF feed 115 may be apportioned by controlling the load and tune settings of the RF match 125 to couple a portion of RF power input at the RF feed 110 out of the RF feed 115 to be dissipated in the dummy load 160. For example, 1000 W can be input at center location of the electrode 105 with the RF feed 110. For a situation where a high etch rate spot is near the RF feed 115 location, the RF match 125 may be set to couple out 100 W to the dummy load 160, which may be rated at 200 W max. Shunting of RF energy from the plasma at the location of the RF feed 115 may reduce the high etch rate spot near this location of the electrode. In further embodiments, where additional RF feeds, such as the RF feed 113 and the RF feed 117 of FIG. 1B, are also coupled to dedicated dummy loads via dedicated matches, these dummy loads may be set to dissipate less power, such as 10W, because the etch rate is not high at those locations.

In another embodiment, the dummy load 160 may be replaced with a third RF feed coupled to the electrode 105 at a third location. For example, the third RF may be an RF feed with an azimuth angle 90° from the RF feed 115, such as the RF feed 113 in FIG. 1B. In such a configuration, RF power between the RF feed 110, RF feed 115 and the third RF feed may be apportioned by controlling the load and tune settings of the RF match 125 to couple a portion of RF power input at the RF feed 110 out of the RF feed 115 and into to the third RF feed. For example, 1000 W may be input at center location of the electrode 105 with the RF feed 110. For a situation where a high etch rate spot is near the RF feed 115, the RF match 125 may be set to couple out 100 W from the RF feed 115 and into the RF feed 113. Removal of RF energy from the RF feed 110 may reduce the high etch rate spot near this location of the electrode. However, in other embodiments described elsewhere herein, where one side of an RF match has a 50 ohm connection, (e.g., a dummy load or 50 ohm cable and RF generator), because the power flows in only one direction as the RF match attempts to match the 50 ohm side, the power delivered to certain locations can be precisely measured more readily than for those embodiments incorporating a third RF feed.

Embodiments of the present invention may be provided as a computer program product, which may include a computer-readable storage medium having stored thereon instructions, which when executed by controller, such as the controller 140 of FIG. 1A, cause the capacitively coupled etch system to etch a substrate 102 with a plasma discharge generated with power provided by the plurality of RF feeds, such as RF feeds 110 and 115. The power splitter 130 and/or the RF matches 120 and 125, as controlled by the controller 140, may vary the division of power between to both the first RF feed 110 and second RF feed 115 as determined by the instructions stored on the computer-readable storage medium. The first RF match 120 and the second RF match 125, as controlled by the controller 140, may impedance match the reactive load of the plasma to couple power to both the first RF feed 110 and the second RF feed 115 to the plasma. In other embodiments described elsewhere herein, computer control of output power across a plurality of RF generators, match load and tune settings across a plurality of RF matches may similarly be accomplished through instructions provided on a computer-readable storage medium.

The computer-readable medium may include, but is not limited to, floppy diskettes, optical disks, CD-ROMs (compact disk read-only memory), and magneto-optical disks, ROMs (read-only memory), RAMs (random access memory), EPROMs (erasable programmable read-only memory), EEPROMs (electrically-erasable programmable read-only memory), magnet or optical cards, flash memory, or other commonly known types of computer-readable medium suitable for storing electronic instructions. Moreover, the present invention may also be downloaded as a computer program product, wherein the program may be transferred from a remote computer to a requesting computer over a wire.

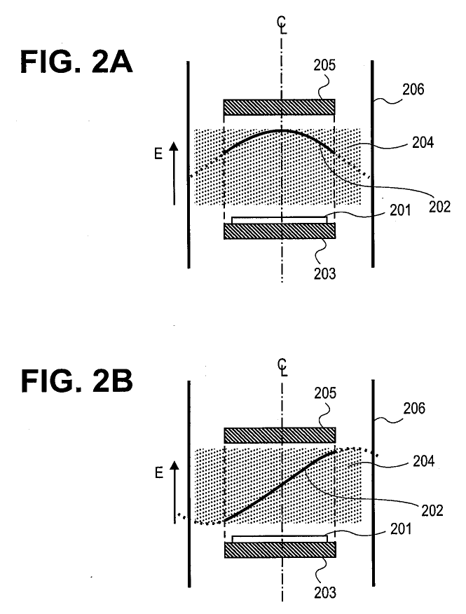

With FIGS. 1A-1C depicting a number of embodiments of a capacitive plasma discharge employing a plurality of RF feeds, the effect of the plurality of RF feeds on the plasma uniformity and etch uniformity is now discussed. FIG. 2A schematically illustrates an axial component of an electric field 202 in the first order capacitor mode of a capacitively coupled plasma 204. Such a condition is typical when at least one of electrodes 205 and 203 is coupled to an RF generator by a single RF feed located in the center of the electrode 205 or 203. It will be appreciated these modes exist only in the plasma and do not extend to chamber walls 206, as denoted by the dashed lines. The axial component of electric field in first order capacitor mode of the capacitively coupled plasma 204 field may be represented by the zeroth order Bessel function at high frequencies of at least 13.56 MHz and at lower frequencies, the Bessel function can be approximately as a constant reducing to the form in AC-circuit theory. Because of this variation in the axial component of electric field where only a center RF feed is adopted, the etch rate shows a center peaked non-uniformity. As ionization efficiencies increase with higher frequency (e.g., from 13.56 MHz up to 162 MHz) this center peaked non-uniformity of the axial electric field has an increasingly negative impact on etch uniformity across a substrate 201. Depending on the etch process conditions, the center-peaked axial electric field may impact etch uniformity in a variety of ways, such as center to edge etch rate variation, center-to-edge feature sidewall passivation variation, center-to-edge ion charging or shadowing variation, etc. The resulting etch non-uniformity may be difficult to reduce or eliminate through tuning of other process parameters, such as process gas distribution.

Upon introduction of a peripheral RF feed point, such as the second RF feed point 115 of FIG. 1A, both the first order capacitor mode depicted in FIG. 2A and the second order capacitor mode of a capacitively coupled plasma schematically illustrated in FIG. 2B are simultaneously excited at high frequencies. Third order and higher capacitor modes may also become significant with introduction of a peripheral RF feed point. The axial electric field 402 corresponding to the second order capacitor mode can be represented by the first order Bessel function and the azimuth angle. Thus, for embodiments where source power is coupled a plurality of RF feeds, such as illustrated in FIG. 1A and FIG. 1B, the location of highest axial field can be controlled both radially and azimuthally within the chamber to improve plasma uniformity. The improved plasma uniformity may thereby improve etching uniformity.

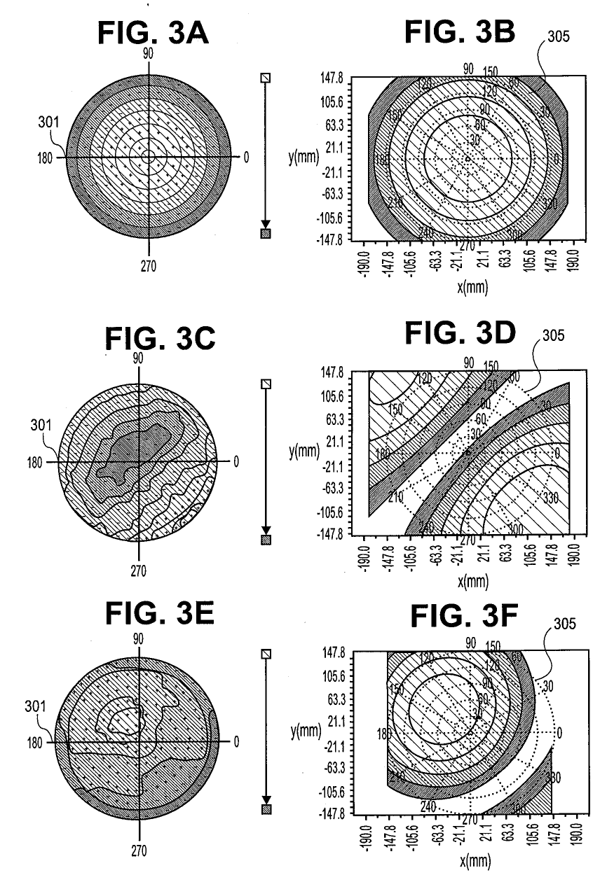

FIG. 3A depicts an experimental measurement of an oxide film etch delta on a substrate 301 plotted as a map across the substrate 301 for a capacitively coupled plasma incorporating an electrode coupled to a 100 MHz RF generator via a single RF feed located at the electrode center. FIG. 3B shows a theoretical model of the axial component of electric field mapped across an electrode 305 for the center fed 100 MHz RF system corresponding to FIG. 3A. In FIG. 3B, the outermost circle represents the circumference of the substrate 301 at 150 mm such that the axis of the electrode 305 is coincident with the axis of the substrate 301. The orientation of both the substrate 301 and the electrode 305 are aligned such that the a-a′ plane of FIG. 1B corresponds to the 0° and 180° azimuth angles of FIG. 3A and FIG. 3B. As denoted by the key associated with both FIGS. 3A and 3B, denser lines in the figures represent a smaller etch delta in FIG. 3A and a smaller axial component of electric field in FIG. 3B. As shown in FIG. 3A, the highest measured etch rate is at the center of the substrate 301 and falls off with radial distance toward the edge of the substrate 301. Similarly, the highest axial component of electric field, or “hot spot” depicted in FIG. 3B is symmetric about the center of the electrode 305.

FIG. 3C depicts an experimental measurement of an oxide film etch rate on the substrate 301 for a capacitively coupled plasma incorporating an electrode coupled to a 100 MHz RF generator via a single RF feed located at the electrode periphery, at the approximate location of the RF feed 116 of FIG. 1B. FIG. 3D shows corresponding theoretical model of the axial electric field across the electrode 305 for the 100 MHz RF system coupled to the RF feed 116. Here again, in FIG. 3D, the outermost circle represents the circumference of the substrate 301 at 150 mm such that the axis of the electrode 305 is coincident with the axis of the substrate 301. The orientation of both the substrate 301 and the electrode 305 are aligned such that the a-a′ plane of FIG. 1B corresponds to the 0° and 180° azimuth angles of FIG. 3C and FIG. 3D. Here too, denser lines in the figures represent a smaller etch delta in FIG. 3C and a smaller axial component of electric field in FIG. 3D. As shown in FIG. 3C, the etch delta across the substrate 301 indicates the etch to be center slow and fastest at a peripheral location proximate to azimuth 3150 corresponding to the RF feed 116 of FIG. 1B. In close agreement, the axial electric field modeled with the zeroth and first order Bessel functions places the hot spot over the peripheral location proximate to azimuth 315°. The theoretical result further indicates an excitation ratio of the power in the second order capacitor mode to the power in the first order capacitor mode is close to 8:1. This indicates RF feed location can dramatically manipulate the strength of the axial component of electric field across an electrode and that the uniformity of an oxide film etched with a high RF frequency of 100 MHz is strongly correlated with the axial component of electric field as modulated across a substrate by the RF feed location.

FIG. 3E depicts an experimental measurement of an oxide film etch rate on the substrate 301 for a capacitively coupled plasma incorporating an electrode coupled to a 100 MHz RF generator via a plurality of RF feeds. A first RF feed is located at the electrode center, such as the RF feed 110 of FIG. 1B and a second RF feed is located at the electrode periphery, at the approximate location of the RF feed 112 of FIG. 1B. FIG. 3D shows corresponding theoretical model of the axial electric field across the electrode 305 for the 100 MHz RF system coupled to both the RF feed 110 and the RF feed 112. As shown in FIG. 3C, the etch delta across the substrate 301 indicates the etch is center fast but with the peak broadened relative to FIG. 3A and slightly shifted from center toward a peripheral location proximate to azimuth 135° corresponding to the RF feed 112 of FIG. 1B. The axial component of electric field modeled for this configuration indicates an excitation ratio of the second order capacitor mode to the first order capacitor mode is close to 1:1. This indicates that multiple RF feed locations can dramatically manipulate the strength of the axial component of electric field across an electrode by varying the proportion of energy dissipated by the first and second capacitor modes in a capacitive plasma discharge. In this manner, etch uniformity may be improved by proportioning energy across multiple RF feeds coupled to the electrode at various radii and azimuth angles, either statically for an entire duration of an etch or dynamically with a time varying apportionment of RF signal power during an etch. Whether applied to dielectric or conductor etch processes, as the RF frequency in capacitive plasma discharges increases for the benefit of higher film etch rates, the etch non-uniformity resulting from the first order capacitor mode will also increase. Therefore, the benefit of multiple RF feeds can be expected to increase.

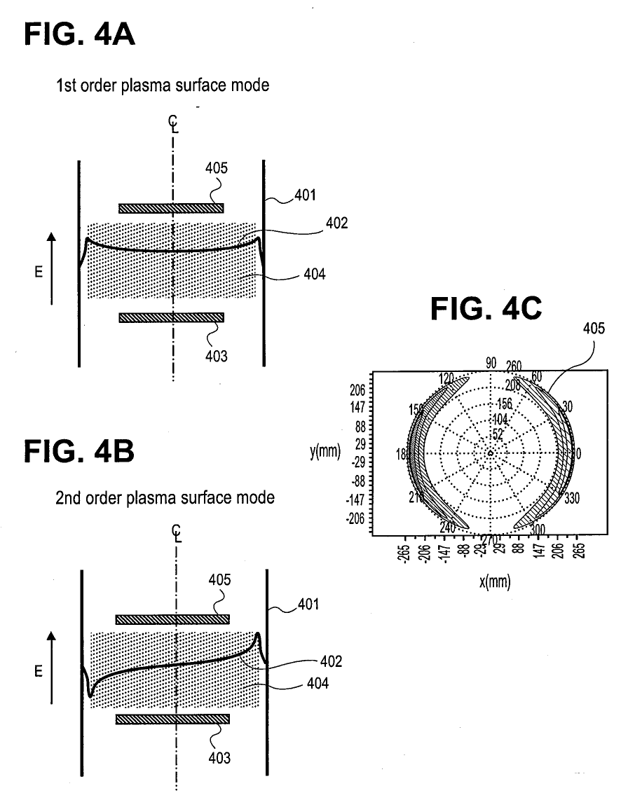

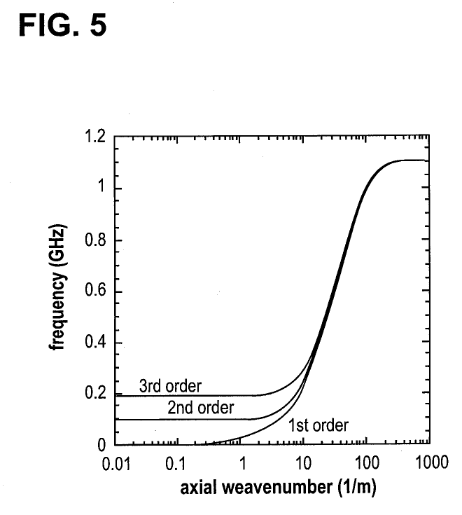

In addition to the capacitor modes described, plasma surface modes also become more significant with the application of higher RF frequencies. An axial electric field 402 trend for the first order plasma surface mode is depicted in FIG. 4A. The axial electric field 402 trend for the second order mode is depicted in FIG. 4B. As the name implies, for such modes, the highest axial electric field between the electrodes 405 and 403 is at the boundary between a chamber wall 401 and a plasma 404. Unlike the capacitor modes, the plasma surface modes exist beyond the plasma, as denoted by the axial electric field 402 extending to the chamber wall 401. FIG. 4C depicts the azimuthal distribution of the second order plasma surface mode with the region of the electrode 405 lacking shading lines having a nominal axial electric field, the regions with dense shading lines near 180° being of lowest axial electric field and those regions near 0° being of highest axial electric field. As further shown in the dispersion curve depicted in FIG. 5, only the second order of the plasma surface mode is excited as a resonant mode when RF frequencies over about 50 MHz are employed. Thus, in the range of about 50-120 MHz additional etch non-uniformity having an azimuthal dependence is introduced. Therefore, with RF frequencies above 50 MHz advantageous for their relatively higher etch rates, the ability to apportion the RF signal across multiple RF feeds is advantageous also for control of the etch nonuniformity attributable to the second order surface modes.

It is to be understood that the above description is intended to be illustrative, and not restrictive. Many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration within the spirit and scope of the appended claims. Accordingly, the specification and drawings are to be regarded in an illustrative sense rather than a restrictive sense. The scope of the invention should, therefore, be determined with reference to the appended claims, along with the full scope of equivalents to which such claims are entitled.

What is claimed is:

1. A capacitively coupled plasma etch chamber comprising:
a first RF power feed coupled to a center of a disc-shaped electrode of the capacitively coupled etch chamber, the first RF power feed further coupled to a first RF match network; and
a second RF power feed coupled to the disc-shaped electrode at a first radius from the center position and a first azimuth angle, the second RF power feed further coupled to a second RF match network.

2. The capacitively coupled plasma etch chamber as in claim 1, wherein the first RF match network is coupled to a first RF power generator and the second RF match network is coupled to a second RF power generator.

3. The capacitively coupled plasma etch chamber as in claim 2, wherein the first and second RF power generators generate power at the same high RF frequency, between 50 MHz and 162 MHz.

4. The capacitively coupled plasma etch chamber as in claim 3, wherein the first RF power generator is configured to provide RF power in phase with that provided by the second RF power generator.

5. The capacitively coupled plasma etch chamber as in claim 1, wherein the first RF match network and the second RF match network are both coupled to a first RF power generator, with a power splitter there between.

6. The capacitively coupled plasma etch chamber as in claim 1, wherein one of the first or second RF match networks is coupled to an RF generator and the other is coupled to a dummy load.

7. The capacitively coupled plasma etch chamber as in claim 6, wherein the dummy load is a 50 ohm load rated for between about 100 and 1000 watts max power.

8. The capacitively coupled plasma etch chamber as in claim 1, further comprising a third RF power feed coupled to the disc-shaped electrode at a second azimuth angle, the third RF power feed coupled to a third RF match network.

9. The capacitively coupled plasma chamber as in claim 8, wherein the first, second and third RF match networks are each coupled to a first RF generator, with a first and second power splitter there between.

10. A method of etching a substrate in a capacitively coupled plasma etch chamber, comprising:
loading a substrate in the chamber;
introducing a process gas; and
energizing the process gas into a plasma with a plurality of RF feeds coupled to a disc-shaped electrode in the chamber, wherein the plurality of RF feeds further includes:
a first RF power feed coupled to a center of a disc-shaped electrode, the first RF power feed further coupled to a first RF match network; and
a second RF power feed coupled to the disc-shaped electrode at a first radius from the center position and a first azimuth angle, the second RF power feed further coupled to a second RF match network.

11. The method as in claim 10, further comprising:
controlling the plasma uniformity by apportioning the total RF power provided to the disc-shaped electrode across the plurality of RF feeds

12. The method as in claim 11, wherein the plurality of RF feeds further includes:
a third RF power feed coupled to the disc-shaped electrode at a second azimuth angle, the third RF power feed further coupled to a third RF match network; and
wherein apportioning the total RF power further comprises:
setting the third RF match network, coupled to a second dummy load, to dissipate a second input power different from the first input power dissipated in the first dummy load.

13. The method as in claim 11, wherein apportioning the total RF power further comprises:
setting a first RF power generator coupled to the first RF match network to a first output power; and
setting a second RF power generator coupled to the second RF match network to a second output power.

14. The method as in claim 11, wherein apportioning the total RF power further comprises:
setting a first RF power generator, coupled to the first RF match network, to a first output power; and
setting the second RF match network to dissipate power, tapped from the second RF feed, in a first dummy load.

15. The method as in claim 11, wherein the apportioning of the total RF power provided to the disc-shaped electrode across the plurality of RF feeds further comprises adjusting the power apportionment across the plurality of RF feeds while the substrate is exposed to the plasma.

16. A computer readable medium, with instructions stored thereon, which when executed by a computer processor of a system, cause the system to perform a method, the method comprising:
loading a substrate in a capacitively coupled plasma etch chamber;
introducing a process gas to the chamber;
energizing the process gas into a plasma with a plurality of RF feeds coupled to a disc-shaped electrode in chamber, wherein the plurality of RF feeds further includes:
a first RF power feed coupled to a center of a disc-shaped electrode, the first RF power feed further coupled to a first RF match network; and
a second RF power feed coupled to the disc-shaped electrode at a first radius from the center position and a first azimuth angle, the second RF power feed further coupled to a second RF match network.

17. The method as in claim 16, further comprising:
controlling the plasma uniformity by apportioning the total RF power provided to the disc-shaped electrode across the plurality of RF feeds.

18. The method as in claim 17, wherein apportioning the total RF power further comprises:
setting a first RF power generator coupled to the first RF match network to a first output power; and
setting a second RF power generator coupled to the second RF match network to a second output power, wherein the first and second RF power generators output power at a single frequency.

19. The method as in claim 17, wherein apportioning the total RF power further comprises:
setting a first RF power generator, coupled to the first RF match network, to a first output power; and
setting the second RF match network to dissipate power, tapped from the second RF feed, in a first dummy load.

20. The method as in claim 19, wherein the plurality of RF feeds further includes:
a third RF power feed coupled to the disc-shaped electrode at a second azimuth angle, the third RF power feed further coupled to a third RF match network; and
wherein apportioning the total RF power further comprises:
setting the third RF match network to dissipate power, tapped from the third RF power feed, in a second dummy load.
